(19) United States
(12) Patent Application Publication
(10) Pub. No.: US 2025/0037964 A1
(43) Pub. Date: Jan. 30, 2025

(54) JIG AND SAMPLE PROCESSING METHOD

(71) Applicant: Kioxia Corporation, Tokyo (JP)

(72) Inventors: Takafumi INAMORI, Yokkaichi Mie (JP); Ken HOSHINO, Yokkaichi Mie (JP); Akira KURAMOTO, Yokkaichi Mie (JP); Jun HIROTA, Yokohama Kanagawa (JP)

(21) Appl. No.: 18/771,970

(22) Filed: Jul. 12, 2024

(30) Foreign Application Priority Data
Jul. 26, 2023 (JP) 2023-121712

(51) Int. Cl. H01J 37/20; H01J 37/28

(52) U.S. Cl. CPC H01J 37/20; H01J 37/28; H01J 2237/20214; H01J 2237/31749

(57) ABSTRACT

A jig includes a support portion, a sample fixing portion, and a stopper. The support portion includes a wall portion extending in a first direction and a second direction perpendicular to the first direction. The sample fixing portion is rotatable, and has a sample holding surface configured to allow a sample to be placed thereon and a sample holding mechanism. The stopper is provided on an upper surface of the wall portion and movable to a position where the sample fixing portion can come into contact therewith when the sample fixing portion is rotated.

### CROSS-REFERENCE TO RELATED APPLICATION(S)

This application is based upon and claims the benefit of priority from Japanese Patent Application No. 2023-121712, filed Jul. 26, 2023, the entire contents of which are incorporated herein by reference.

### FIELD

Embodiments described herein relate generally to a jig and a sample processing method.

### BACKGROUND

To produce a sample to be observed with an electron microscope or the like, a charged particle beam device may be used to microfabricate the sample with an ion beam. When there are different structures in the sample, for example, one of the structures is processed at a rate higher than that of the other structures when an incidence direction of the ion beam and a structure boundary in the sample overlap, and curtaining may occur. Similarly, even when the sample has a periodic structure, curtaining may occur when the incidence direction of the ion beam and a structure pattern in the sample overlap.

### DESCRIPTION OF THE DRAWINGS

FIG. 1 is a schematic view illustrating a configuration example of a charged particle beam device according to a first embodiment.

FIGS. 2 and 3 are side views of a configuration example of a jig according to the first embodiment.

FIG. 4 is a top view illustrating the configuration example of the jig according to the first embodiment.

FIG. 5 is a side view of the configuration example of the charged particle beam device according to the first embodiment with a sample placed thereon.

FIGS. 6A and 6B are side views illustrating a start of an angle adjustment operation of the sample using the jig according to the first embodiment.

FIG. 6C is a top view illustrating the start of the angle adjustment operation of the sample using the jig according to the first embodiment.

FIGS. 7A and 7B are side views illustrating a first example of an angle adjustment operation of the sample using the jig according to the first embodiment.

FIG. 7C is a top view illustrating the first example of the angle adjustment operation of the sample using the jig according to the first embodiment.

FIGS. 8A and 8B are side views illustrating a second example of an angle adjustment operation of the sample using the jig according to the first embodiment.

FIG. 8C is a top view illustrating the second example of the angle adjustment operation of the sample using the jig according to the first embodiment.

FIG. 9 is a flowchart depicting steps of a sample processing method according to the first embodiment.

FIG. 10 is a side view illustrating a configuration example of the jig according to a modification of the first embodiment.

FIG. 11 is a top view illustrating the configuration example of the jig according to the modification of the first embodiment.

FIG. 12 is a top view illustrating a configuration example of the jig according to a second embodiment.

FIG. 13 is a top view illustrating a configuration example of the jig according to a third embodiment.

FIG. 14 is an enlarged view illustrating an example of a cross-sectional view of the sample according to a fourth embodiment.

FIGS. 15A and 15B are enlarged side views of a cross-section of the sample in the fourth embodiment when an ion beam is emitted.

FIG. 15C is an enlarged top view of the sample in the fourth embodiment after the emission of the ion beam.

FIG. 16 is a top view illustrating an example of a hole in the fourth embodiment.

### DETAILED DESCRIPTION

Embodiments provide a jig and a sample processing method capable of easily adjusting an emission position of a charged particle beam with respect to a sample.

In general, according to one embodiment, a jig according to an embodiment includes a support portion, a sample fixing portion, and a stopper. The support portion includes a wall portion extending in a first direction and a second direction perpendicular to the first direction. The sample fixing portion is rotatable and has a sample holding surface configured to allow a sample to be placed thereon and a sample holding mechanism. The stopper is provided on an upper surface of the wall portion and movable to a position where the sample fixing portion can come into contact therewith when the sample fixing portion is rotated.

Hereinafter, embodiments according to the present disclosure will be described with reference to the drawings. The present embodiment does not limit the scope of the present disclosure. The drawings are schematic or conceptual, and a proportion and the like of each portion are not necessarily the same as the actual ones. In the description of the specification and the drawings, components similar to those previously described with reference to a preceding figure are denoted by the same reference numerals, and detailed description thereof will be appropriately omitted.

### First Embodiment

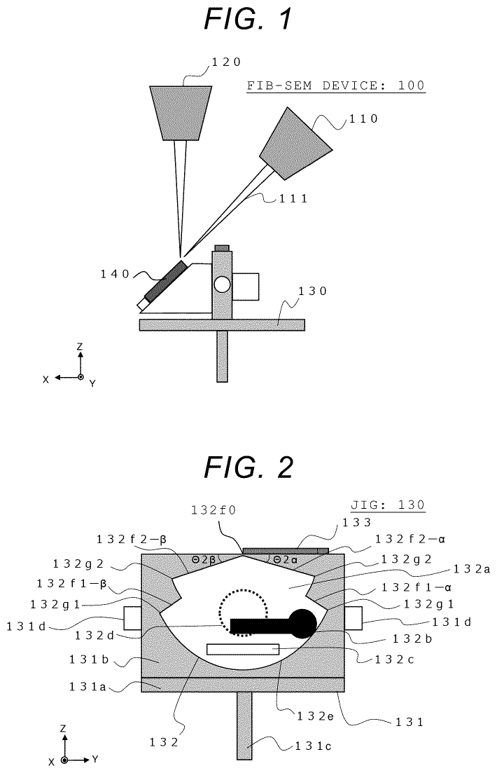

FIG. 1 is a schematic view illustrating a configuration example of a charged particle beam device according to a first embodiment. In the charged particle beam device according to the first embodiment, for example, a sample held in a jig is processed by an ion beam. The charged particle beam device may be, for example, a focused ion beam (FIB) device. In addition, the charged particle beam device may be a FIB-SEM (scanning electron microscope) device including a FIB device and an SEM. Hereinafter, the FIB-SEM device will be described as an example.

A FIB-SEM device 100 includes a FIB column 110 and an SEM column 120 and further includes a jig 130 capable of holding a sample.

The FIB column 110 emits an ion beam 111 by generating and focusing ions. When the ion beam 111 from the FIB column 110 is emitted to a sample 140 placed on the jig 130, any location of the sample 140 can be processed.

The SEM column 120 emits an electron beam and detects secondary electrons emitted from the sample 140 as a result of the emission of the electron beam. After the ion beam 111 from the FIB column 110 is emitted to the sample 140, the emission of the electron beam and the detection of the secondary electrons by the SEM column 120 are performed at any location of the sample 140 emitted by the ion beam 111. Accordingly, any location of the sample 140 can be observed.

The jig 130 can hold the sample 140. The sample 140 is placed on and fixed to the jig 130. A portion of the jig 130 on which the sample 140 is placed is inclined. In other words, the jig 130 has an inclined surface on which the sample 140 can be placed. The jig 130 can be tilted in a Z direction around a Y axis. For example, when it is desired to adjust an angle of the sample 140 fixed to the jig 130 with respect to the ion beam 111 emitted from the FIB column 110, the jig 130 may be tilted in the Z direction around the Y axis.

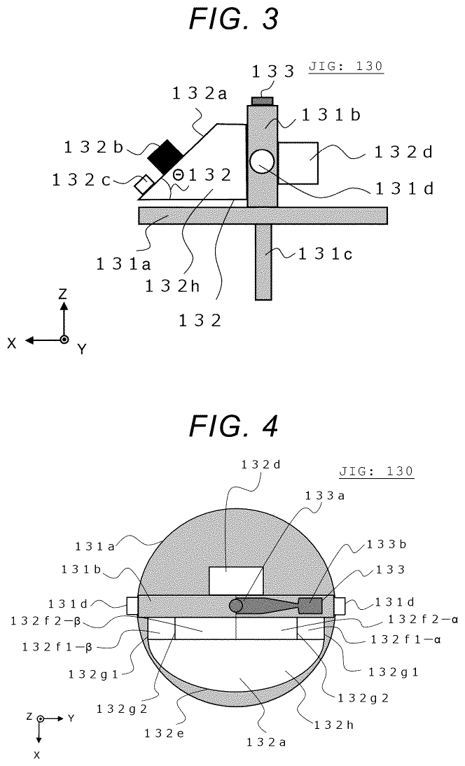

FIGS. 2 and 3 are side views of a configuration example of the jig 130 according to the first embodiment. FIG. 4 is a top view of the configuration example of the jig 130 according to the first embodiment. All elements of the jig 130 in FIGS. 2, 3, and 4 are in initial positions.

The jig 130 can hold the sample 140. For example, it is preferable to use a material for the jig 130 that is resistant to dust generation, sublimation, and melting due to the ion beam and the electron beam. Further, it is preferable to use a conductive material connected to the FIB-SEM device 100 such that charging by electrons or ions can be prevented when emitted by the electron beam or the ion beam.

To improve the controllability of the jig 130, for example, it is preferable to use a relatively light metal as the jig 130. For example, aluminum may be used for the jig 130. In the jig 130, the same material or different materials may be used for the elements to be described later. For example, all the elements of the jig 130 may be formed of aluminum, or a part of the elements of the jig 130 may be formed of aluminum and the other part of the elements may be formed of a material other than aluminum.

The jig 130 includes a support portion 131, a sample fixing portion 132, and a stopper 133.

The support portion 131 includes a floor portion 131a, a wall portion 131b, a support shaft 131c, and a pair of fixing portions 131d. It is noted that FIGS. 2, 3, and 4 illustrate an example in which the pair of fixing portions 131d are provided, but the present disclosure is not limited thereto. For example, only one fixing portion 131d may be provided. The following description will focus mainly on a configuration of one fixing portion 131d.

The floor portion 131a extends in an X direction and a Y direction. For example, the floor portion 131a may have a circular shape when viewed from the Z direction.

The wall portion 131b extends from the floor portion 131a in the Y direction and the Z direction. When the floor portion 131a has a circular shape, the wall portion 131b may be provided on a diameter of the floor portion 131a. In this case, a length of the wall portion 131b in the Y direction may be the same as a length of the diameter of the floor portion 131a. The wall portion 131b has a hole for rotatably holding a rotation shaft 132d in the sample fixing portion 132 to be described later and holes in which the fixing portions 131d are screwed to be described later. A height of the wall portion 131b in the Z direction may be, for example, the same as or larger than a height of the sample fixing portion 132 to be described later in the Z direction. More specifically, for example, the height of the wall portion 131b in the Z direction may be the same as or higher than a height of a roof portion 132f of the sample fixing portion 132 to be described later in a state in which the rotation shaft 132d in the sample fixing portion 132 is held at an initial position.

The support shaft 131c extends in the Z direction from the floor portion 131a. More specifically, the support shaft 131c extends in the Z direction from a surface of the floor portion 131a opposite to a surface of the floor portion 131a in contact with the wall portion 131b. That is, the support shaft 131c and the wall portion 131b extend in opposite directions in the Z direction. When the floor portion 131a has a circular shape, for example, the support shaft 131c may extend in the Z direction from a central portion of the circle in the floor portion 131a.

The fixing portion 131d is provided on a side surface of the wall portion 131b. Specifically, the fixing portion 131d may be provided, for example, on a side surface of the wall portion 131b in which the Y direction is a normal direction. That is, the fixing portion 131d may be provided on, for example, a side surface of the wall portion 131b on which the sample fixing portion 132 and the stopper 133 to be described later are not provided.

The fixing portion 131d is screwed into a hole extending in the Y direction from the side surface of the wall portion 131b. When the fixing portion 131d is moved to the inner side of the wall portion 131b, one end portion of the fixing portion 131d comes into contact with the rotation shaft 132d to be described later inside the wall portion 131b. Accordingly, the rotation shaft 132d is fixed inside the wall portion 131b, and the sample fixing portion 132 is also fixed at a predetermined position. In the state in which the fixing portion 131d is screwed into the wall portion 131b, the other end portion of the fixing portion 131d is exposed from the wall portion 131b. The other end portion of the fixing portion 131d may protrude in the Y direction from the side surface of the wall portion 131b, or may be located inside the side surface of the wall portion 131b.

The fixing portion 131d and the hole formed in the side surface of the wall portion 131b may be, for example, screwed together.

A plurality of the fixing portions 131d may be provided and may be provided on, for example, side surfaces on which the sample fixing portion 132 and the stopper 133 to be described later are not provided among side surfaces of the wall portion 131b, that is, two side surfaces in which the Y direction is the normal direction. In this case, the rotation shaft 132d is in contact with the pair of fixing portions 131d at two locations and is fixed inside the wall portion 131b.

Hereinafter, a case will be described as an example in which the fixing portion 131d can be screwed into the hole formed in the side surface of the wall portion 131b. It is noted that the fixing portion 131d may be formed of, for example, rubber in addition to the above-described screw, and may fix the rotation shaft 132d by being press-fit in the hole extending in the Y direction from the side surface of the wall portion 131b.

The sample fixing portion 132 includes a sample holding surface 132a, a sample holding portion 132b, a step 132c, the rotation shaft 132d, an arc portion 132e, the roof portion 132f, and a shoulder portion 132g. The sample holding surface 132a, the sample holding portion 132b, the step 132c, the arc portion 132e, the roof portion 132f, and the shoulder portion 132g, that is, portions of the sample fixing portion 132 other than the rotation shaft 132d function as a sample placement portion 132h. The sample placement portion 132h of the sample fixing portion 132 may have, for example, a semi-cylindrical shape.

The sample holding surface 132a is a surface located opposite to a surface of the sample fixing portion 132 in contact with the wall portion 131b. In other words, the sample holding surface 132a is a surface located opposite to a surface of the sample placement portion 132h in contact with the wall portion 131b. The sample 140 is placed on the sample holding surface 132a. It is preferable that the sample 140 is placed such that a surface having an observation target portion is located opposite to a surface in contact with the sample holding surface 132a. Here, the observation target portion can also be said to be a portion of the sample 140 that is processed by the ion beam 111 emitted from the FIB column 110. When viewed from the Y direction, the sample holding surface 132a is inclined such that an angle θ132 formed with respect to the arc portion 132e is an acute angle. For example, the angle θ132 may be the same as an emission angle of the ion beam 111 emitted from the FIB column 110.

The sample holding surface 132a is provided with the sample holding portion 132b and the step 132c. The sample holding portion 132b includes, for example, a screw and a plate spring. The sample holding portion 132b functions as a part of a sample holding mechanism. In a state in which the sample 140 is placed on the sample holding surface 132a, the sample 140 is fixed to the sample holding surface 132a by sandwiching a place other than the observation target portion of the sample 140 with the plate spring.

When viewed from the Y direction, the step 132c protrudes from the sample holding surface 132a in at least one of the X direction and the Z direction or in the X direction and the Z direction. When the sample 140 has a substantially rectangular shape, the step 132c supports at least one edge of the sample 140. The step 132c may be formed by a linear member or two or more point-shaped members as long as the step 132c can support at least one edge of the sample 140.

The step 132c functions as another part of the sample holding mechanism. That is, the sample holding portion 132b and the step 132c cooperatively function as the sample holding mechanism. It is noted that only the sample holding portion 132b may function as the sample holding mechanism, and only the step 132c may function as the sample holding mechanism. The step 132c may be integrally formed with the sample holding surface 132a or may be attached separately from the sample holding surface 132a. For example, the step 132c may protrude from the sample holding surface 132a, or the step 132c may be attached to the substantially flat sample holding surface 132a as a protruded member.

It is preferable that the step 132c can hold the sample 140 such that one edge of the sample 140 is substantially parallel to the floor portion 131a in the state in which the rotation shaft 132d is held at the initial position when the sample 140 is placed on the sample holding surface 132a and at least a part of one surface of the sample 140 is in contact with the step 132c. In other words, it is preferable that the step 132c can hold the sample 140 such that one edge of the sample 140 is substantially parallel to the floor portion 131a in the Y direction in the state in which the rotation shaft 132d is held at the initial position. Accordingly, for example, even when the sample 140 is replaced and a new sample is placed on the sample holding surface 132b, an angle of the sample with respect to a Y axis can be made uniform.

The rotation shaft 132d extends from the sample placement portion 132h in the X direction in the sample fixing portion 132. The rotation shaft 132d penetrates the wall portion 131b and is rotatably held by the hole of the wall portion 131b. The rotation shaft 132d may be, for example, a screw that allows the sample fixing portion 132 to rotate. When the rotation shaft 132d is operated, the sample fixing portion 132 is rotatable with respect to the wall portion 131b around the rotation shaft 132d. The sample fixing portion 132 may rotate clockwise or counterclockwise with respect to the wall portion 131b around the rotation shaft 132d.

In the sample fixing portion 132, the sample placement portion 132h has, for example, a columnar shape and includes the arc portion 132e. In this case, the arc portion 132e has an arc shape when viewed from the X direction and corresponds to an outer circumferential portion in the columnar shape. A radius of the arc portion 132e is, for example, smaller than the length in the Y direction and the height in the Z direction of the wall portion 131b. The sample fixing portion 132 includes the arc portion 132e, and accordingly, it is possible to prevent interference with the floor portion 131a when the sample fixing portion 132 rotates. Accordingly, since a distance between the sample fixing portion 132 and the floor portion 131a can be shortened, the entire jig 130 can be implemented in a space-saving manner. Further, since the sample fixing portion 132 is held by the floor portion 131a via the arc portion 132e, a load due to gravity when the rotation shaft 132d is held by the hole in the wall portion 131b can be reduced by appropriately setting the radius of the arc portion 132e.

When viewed from the X direction, the sample fixing portion 132 may be provided with the roof portion 132f that is inclined from a tip portion 132f0, which is at a center of a circle formed by the arc portion 132e, hereinafter referred to as circle center of the arc portion 132e. In other words, the roof portion 132f may not be parallel to an upper surface of the wall portion 131b in the support portion 131. The roof portion 132f is inclined such that the tip portion 132f0 thereof is closest to the upper surface of the wall portion 131b and the roof portion 132f gradually moves away from the upper surface of the wall portion 131b. That is, the roof portion 132f is an upper surface of the sample fixing portion 132 that is inclined from the tip portion 132f0 toward the floor portion 131a. As indicated by 132f1 and 132f2 in FIG. 2, a plurality of the roof portions 132f may be provided. When viewed from the X direction, the sample fixing portion 132 may be provided with a plurality of the roof portions 132f and a plurality of the shoulder portions 132g to be described later by cutting end portions in a semicircular shape including the arc portion 132e. An extension line of each of the roof portions 132f may or may not overlap the circle center of the arc portion 132c.

The roof portion 132f2 includes, for example, a roof portion 132f2-α and a roof portion 132f2-β. When the sample fixing portion 132 is viewed from the X direction, a rotation angle from a state in which the sample placement portion 132h and the rotation shaft 132d are held at initial positions until the stopper 133 to be described later and the roof portion 132f2 come into contact with each other is substantially the same as an angle of an inclination angles θ2α and θ2β of the roof portion 132f2. In other words, when the sample fixing portion 132 is viewed from the X direction, a rotatable angle of the sample fixing portion 132 from the state in which the sample placement portion 132h and the rotation shaft 132d are held at the initial positions until the stopper 133 to be described later and the roof portion 132f2 come into contact with each other is the inclination angle θ2α or θ2β.

Similar to the roof portion 132f2, the roof portion 132f1 includes, for example, a roof portion 132f1-α and a roof portion 132f1-β. When the sample fixing portion 132 is viewed from the X direction, a rotatable angle of the sample fixing portion 132 from the state in which the sample placement portion 132h and the rotation shaft 132d are held at the initial positions until the stopper 133 to be described later and the roof portion 132f1 come into contact with each other is an inclination angle θ1α or θ1β (not illustrated).

The inclination angle θ2α of the roof portion 132f2-α and the inclination angle θ2β of the roof portion 132f2-β may be the same or different. The inclination angle θ1α of the roof portion 132f1-α and the inclination angle θ1β of the roof portion 132f1-β may be the same or different. When the inclination angles are different, more inclination angles can be set than when the inclination angles are the same for θ1α and θ1β, and θ2α and θ2β. Accordingly, when there is a plurality of samples having different optimal inclination angles for the measure of the curtaining, the types of samples that can be placed on the same jig 130 increase.

It is noted that the circle center of the arc portion 132e and the rotation shaft 132d of the sample fixing portion 132 do not necessarily coincide with each other in the sample fixing portion 132. In this case, the inclination angles θ1α, θ1β, θ2α, and 02ß are not exactly the same as the rotation angle of the sample fixing portion 132. Also in this case, the sample 140 fixed to the sample fixing portion 132 can be rotated according to the inclination angles θ1α, θ1β, θ2α, and θ2β such that an angle from the initial position with respect to the emission direction of the ion beam 111 changes.

In the sample fixing portion 132, a shoulder portion 132g1 and a shoulder portion 132g2 are provided between the roof portion 132f1 and the arc portion 132e and between the roof portion 132f1 and the roof portion 132f2, respectively. The shoulder portion 132g2 is a part of the roof portion 132f2 and is an end portion opposite to the circle center when the circle center is treated as one end portion in the roof portion 132f2-α and the roof portion 132f2-β. The shoulder portion 132g1 is a part of the roof portion 132f1 and is an end portion serving as a boundary between the roof portion 132f1-α and the arc portion 132e and between the roof portion 132f1-β and the arc portion 132c. A plurality of the shoulder portions 132g may be provided similarly to the roof portion 132f. In this case, when the stopper 133 to be described later and the roof portion 132f come into contact with each other, for example, when at least the shoulder portion 132g comes into contact with a lower surface of the stopper 133, the rotation of the sample fixing portion 132 is stopped.

The stopper 133 is provided on the upper surface of the wall portion 131b in the Z direction. The stopper 133 includes a base portion 133a and a tip portion (protruded portion) 133b. The base portion 133a of the stopper 133 is rotatably provided on the upper surface of the wall portion 131b along an X-Y plane. When viewed from the Z direction, the tip portion 133b of the stopper 133 can protrude from the wall portion 131b in the X-Y plane. In other words, the stopper 133 can move from an initial position at which the stopper 133 does not protrude from the wall portion 131b in the X direction when viewed from the Z direction to a protrusion position at which at least a part of the stopper 133 protrudes from the wall portion 131b in the X direction when viewed from the Z direction. When the sample fixing portion 132 is rotated in a state in which the stopper 133 protrudes from the wall portion 131b, the roof portion 132f comes into contact with the lower surface of the stopper 133. The stopper 133 has a function of limiting a range of the rotation of the sample fixing portion 132 around the rotation shaft 132d.

Two stoppers 133 may be provided to match the clockwise rotation and the counterclockwise rotation of the sample fixing portion 132. In the first embodiment, an axis of the stopper 133 is provided near a center of the upper surface of the wall portion 131b in the Z direction, and the stopper 133 is rotatable. However, a shape of the stopper 133 is not limited thereto.

When the sample fixing portion 132 is rotated around the rotation shaft 132d, the stopper 133 comes into contact with the sample fixing portion 132 at a predetermined position. That is, when the sample fixing portion 132 is rotated around the rotation shaft 132d, the roof portion 132f of the sample fixing portion 132 and the lower surface of the stopper 133 come into contact with each other. When the roof portion 132f comes into contact with the lower surface of the stopper 133, an angle of a surface of the sample 140 having the observation target portion with respect to the emission direction of the ion beam 111 can be adjusted by stopping the rotation of the sample fixing portion 132.

The tip portion 133b of the stopper 133 may be formed as, for example, a protruded portion. Hereinafter, the tip portion 133b of the stopper 133 is also referred to as a protruded portion 133b. For example, the protruded portion 133b may be formed in the stopper 133 to match the number of the roof portions 132f. The protruded portion 133b is an end portion of the stopper on a side opposite to the base portion 133a fixed to the upper surface of the wall portion 131b in the Z direction, that is, is an example of the shape on a tip portion 133b side. The stopper 133 provided with the protruded portion does not have a linear shape from the base portion 133a to the tip portion 133b on the X-Y plane. That is, the stopper 133 has a shape in which a width thereof is increased from the base portion 133a to the tip portion 133b.

A width of the base portion 133a and a width of the tip portion (protruded portion) 133b of the stopper 133 may be substantially the same. When the width of the base portion 133a and the width of the tip portion (protruded portion) 133b in the stopper 133 are substantially the same, the width of the stopper 133 from the base portion 133a to the tip portion (protruded portion) 133b is reduced, and the tip portion (protruded portion) 133b has approximately the same width as the base portion 133a. According to such a shape, when the protruded portion of the stopper 133 protrudes from the wall portion 131b in the X direction, the stopper 133 can come into contact with the roof portion 132f1 while avoiding coming into contact with the roof portion 132f2.

For example, when n is a natural number, the stopper 133 includes n−1 protruded portions when the number of the roof portions 132f is n. When the stopper 133 includes two or more protruded portions as illustrated in FIG. 11, in the X-Y plane, a width of each of the two or more protruded portions may be larger than that of the base portion 133a, or the width of the protruded portions may be substantially the same as the width of the base portion 133a. If the width of the protruded portions is substantially the same as the width of the base portion 133a when the stopper 133 includes two or more protruded portions, in the X-Y plane, a protruded portion close to the base portion 133a may have a shape in which the width is gradually reduced after the width increases. With such a shape, when the width of the other protruded portion is increased, a protruded portion having the same width (substantially the same width as the base portion 133a when viewed from the Z direction) as the protruded portion close to the base portion 133a can be provided. That is, the width of the plurality of protruded portions can be substantially the same as the width of the base portion 133a by increasing the width of the protruded portion and then reducing the width gradually.

Even when there is a plurality of the roof portions 132f such as the roof portion 132f1 and the roof portion 132f2 as illustrated in FIG. 2, since the stopper 133 includes the protruded portions, each roof portion 132f can be brought into contact with the single stopper 133 by adjusting a rotation amount of the single stopper 133. That is, when the lower surface of the stopper 133 and the roof portion 132f1 are to be brought into contact with each other, the stopper 133 can come into contact with the roof portion 132f1 while avoiding coming into contact with the roof portion 132f2 by protruding the protruded portion of the stopper 133 from the wall portion 131b in the X direction.

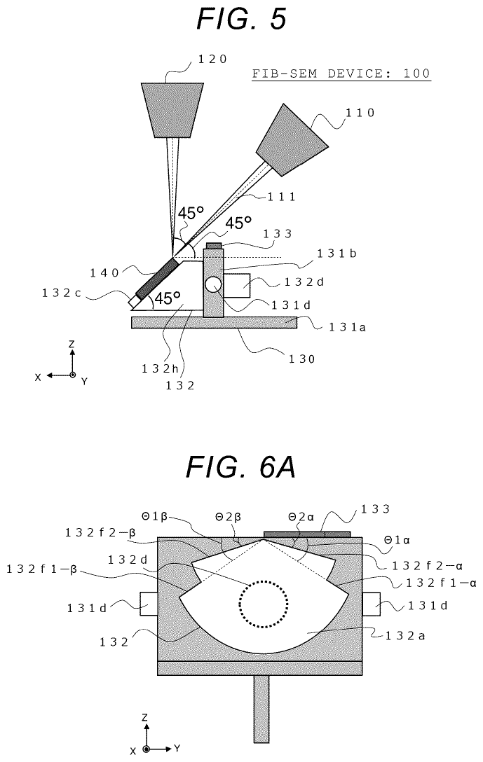

FIG. 5 is a side view of a configuration example of the charged particle beam device according to the first embodiment with the sample 140 placed thereon. In the FIB-SEM device 100, the ion beam 111 emitted from the FIB column 110 may be emitted substantially parallel to a surface of the sample 140 placed on the jig 130. For example, when the inclination angle θ132 in the sample fixing portion 132 is set to 45 degrees, the FIB column 110 emits the ion beam 111 from a position inclined by 45 degrees from a Z axis.

The ion beam 111 emitted from the FIB column 110 is converged at one point. In other words, the ion beam 111 has a conical shape with a focal point as an apex and has a beam width at locations other than the focal point. The beam width is defined as an unfocused portion of the ion beam 111.

When the ion beam 111 emitted from the FIB column 110 is emitted substantially parallel to the surface of the sample 140 placed on the jig 130, the unfocused portion of the ion beam 111 is also emitted to the sample. Therefore, the ion beam 111 processes the sample 140 to be slightly inclined with respect to the surface of the sample in a depth direction. That is, structures with different depths depending on locations can be observed in an emission location of the ion beam 111 on the sample 140. Accordingly, by one emission of the ion beam 111, a pattern shape in the depth direction and a stacked film of the sample 140 can be observed. When a location to be observed in a sample has a structure in which thin films are stacked or has a comparative shallow hole pattern, a structure of the thin film can be observed in detail by emitting the ion beam 111 substantially in parallel to the surface of the sample by using the jig 130.

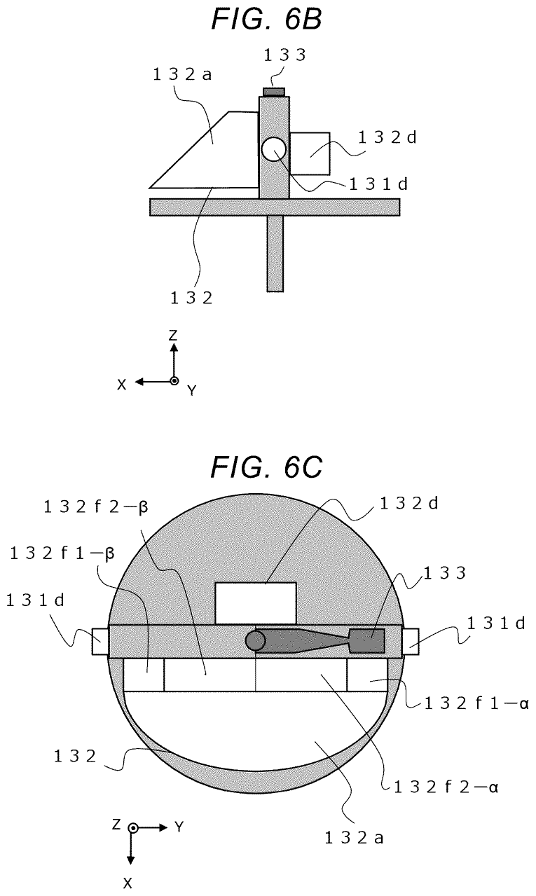

FIGS. 6A to 8C are views illustrating examples of an angle adjustment operation of the sample 140 using the jig 130 according to the first embodiment. FIGS. 6A, 7A, and 8A are views of the jig 130 viewed from the X direction. FIGS. 6B, 7B, and 8B are views of the jig 130 viewed from the Y direction. FIGS. 6C, 7C, and 8C are views of the jig 130 as viewed from the Z direction. It is noted that in FIGS. 6A to 8C, the elements described above are omitted as appropriate.

FIGS. 6A to 6C illustrates the jig 130 in which the sample fixing portion 132 is held at the initial position. The sample fixing portion 132 may not be in contact with the stopper 133. For example, in the jig 130 in the state illustrated in FIGS. 6A to 6C, the sample 140 is placed on the sample holding surface 132a.

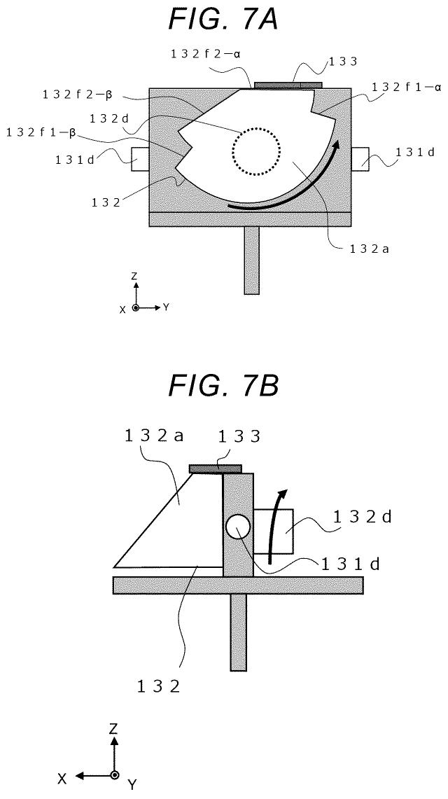

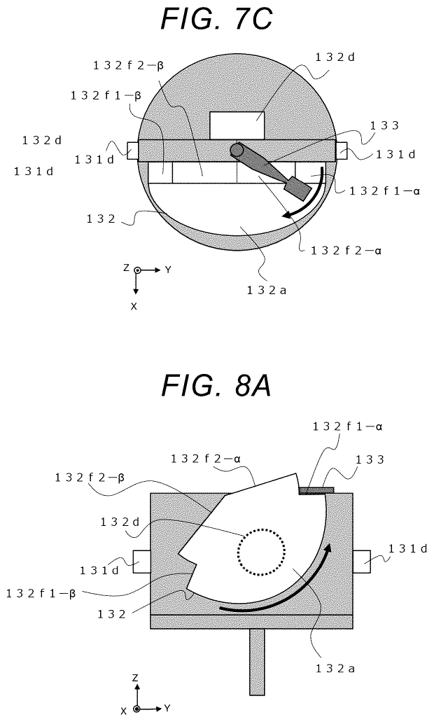

FIGS. 7A to 7C illustrate a state in which the sample fixing portion 132 is rotated one step. That is, FIGS. 7A to 7C illustrate a state in which the sample fixing portion 132 is rotated until the roof portion 132f2-α and the lower surface of the stopper 133 come into contact with each other, and the rotation of the sample fixing portion 132 is stopped while maintaining the contact state. The sample fixing portion 132 is rotated by the inclination angle θ2α illustrated in FIG. 6A, comes into contact with the lower surface of the stopper 133, and stops the rotation. After the rotation of the sample fixing portion 132 is stopped, the fixing portion 131d is rotated until one end of the fixing portion 131d provided in the wall portion 131b comes into contact with the rotation shaft 132d inside the wall portion 131b, and the sample fixing portion 132 is tightened. Accordingly, the fixing portion 131d fixes the sample fixing portion 132 at the position after the rotation.

When the sample 140 is placed on the jig 130, the sample 140 also tilts to match the rotation of the sample fixing portion 132, and an angle of the sample 140 with respect to the emission direction of the ion beam 111 changes.

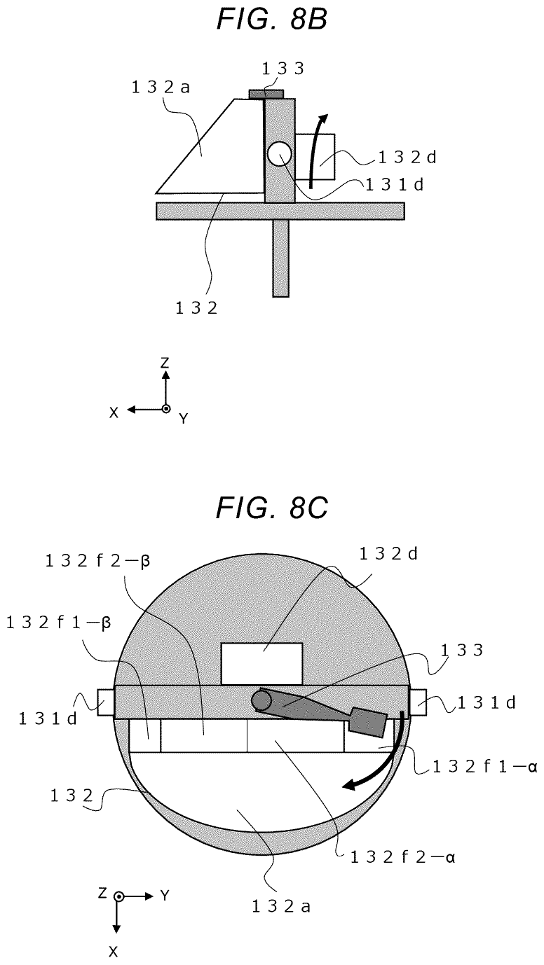

FIGS. 8A to 8C illustrate a state in which the sample fixing portion 132 is rotated by two steps. That is, FIGS. 8A to 8C illustrate a state in which the sample fixing portion 132 is rotated until the roof portion 132f1-α and the lower surface of the stopper 133 come into contact with each other, and the rotation of the sample fixing portion 132 is stopped while maintaining the contact state. The sample fixing portion 132 is rotated by the inclination angle θ1α illustrated in FIG. 6A, comes into contact with the lower surface of the stopper 133, and stops the rotation. After the rotation of the sample fixing portion 132 is stopped, the fixing portion 131d is rotated until one end of the fixing portion 131d provided in the wall portion 131b comes into contact with the rotation shaft 132d inside the wall portion 131b, and the sample fixing portion 132 is tightened. Accordingly, the fixing portion 131d fixes the sample fixing portion 132 at the position after the rotation.

When the sample 140 is placed on the jig 130, the sample 140 also tilts to match the rotation of the sample fixing portion 132, and an angle of the sample 140 with respect to the emission direction of the ion beam 111 changes.

Next, a sample processing method using the jig 130 will be described.

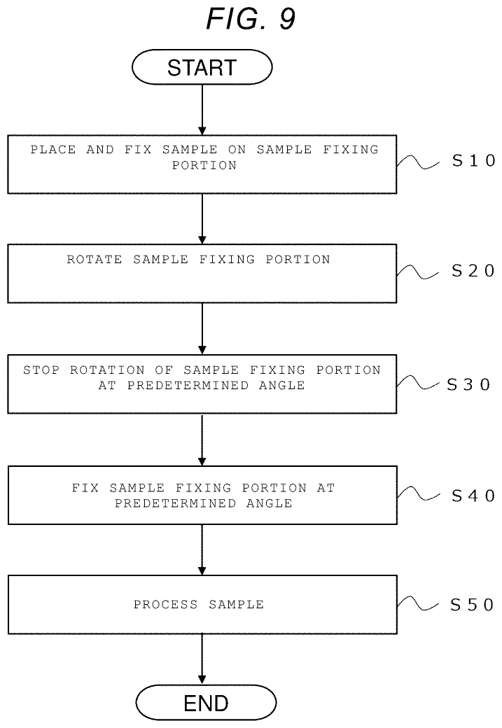

FIG. 9 is a flowchart depicting steps of a sample processing method according to the first embodiment.

First, the sample 140 is placed on the sample holding surface 132a of the sample fixing portion 132 of the jig 130. At this time, at least one edge of the sample 140 may be supported by the step 132c. After the sample 140 is placed on the sample holding surface 132a, the sample 140 is fixed by the sample holding portion 132b (S10).

After the sample 140 is fixed to the sample fixing portion 132, the sample fixing portion 132 is rotated around the rotation shaft 132d with respect to the wall portion 131b (S20). The sample fixing portion 132 may rotate clockwise or counterclockwise around the X direction.

As described with reference to FIGS. 6A to 8C, the sample fixing portion 132 is rotated until the lower surface of the stopper 133 comes into contact with the roof portion 132f. Accordingly, the angle of the sample 140 with respect to the emission direction of the ion beam 111 is adjusted to a predetermined angle. At this time, the rotation angle of the sample fixing portion 132 can be determined by the stopper 133 provided on the upper surface of the wall portion 131b in the Z direction. More specifically, when the sample fixing portion 132 is rotated around the rotation shaft 132d, the roof portion 132f in the sample fixing portion 132 and the lower surface of the stopper 133 come into contact with each other. When the lower surface of the stopper 133 comes into contact with the roof portion 132f, the rotation of the sample fixing portion 132 is stopped (S30). That is, by appropriately setting the inclination angle of the roof portion 132f, the rotation angle of the sample fixing portion 132 can be adjusted to a desired range. It is noted that for example, the inclination angle of the roof portion 132f may be changed to an appropriate angle by an operator. For example, when the roof portion 132f2 and the lower surface of the stopper 133 come into contact with each other, the sample fixing portion 132 may be inclined by 5 degrees as compared with the state of being held at the initial position. In this case, the inclination angle θ2α of the roof portion 132f is 5 degrees. For example, when the roof portion 132f1 and the lower surface of the stopper 133 come into contact with each other, the sample fixing portion 132 may be inclined by 10 degrees as compared with the state of being held at the initial position. In this case, the inclination angle θ1α of the roof portion 132f is 10 degrees. In this way, the operator using the jig 130 may change the inclination angle of the roof portion 132f and the number of the roof portions 132f depending on an angle at which the sample is to be tilted.

After the lower surface of the stopper 133 comes into contact with the roof portion 132f and the rotation of the sample fixing portion 132 is stopped, the sample fixing portion 132 is fixed by the fixing portion 131d such that the sample fixing portion 132 does not move from the position after the rotation (S40). After the rotation of the sample fixing portion 132 is stopped, the fixing portion 131d is rotated until one end of the fixing portion 131d provided in the wall portion 131b comes into contact with the rotation shaft 132d in the wall portion 131b, and the sample fixing portion 132 is tightened.

After the sample fixing portion 132 stops rotating and is fixed at a predetermined position, the ion beam 111 is emitted from the FIB column 110 to process the sample 140 (S50). It is noted that when the stopper 133 protruding from the wall portion 131b is present between the ion beam 111 and the sample 140 in the X-Y plane, the stopper 133 may block the incidence of the ion beam 111 on the sample 140. When the stopper 133 overlaps a trajectory of the ion beam 111, the stopper 133 may be returned to the initial position after the sample fixing portion 132 is fixed by the fixing portion 131d. That is, after the rotation of the sample fixing portion 132 is stopped by the stopper 133 and the sample fixing portion 132 is fixed by the fixing portion 131d, the stopper 133 may be returned to the upper surface of the wall portion 131b in the Z direction, which is the initial position, when the ion beam 111 is emitted from the FIB column 110.

After the ion beam 111 is emitted from the FIB column 110 to process any location of the sample 140, a surface to be processed of the sample 140 is observed by using the SEM column 120.

It is noted that regarding the roof portion 132f in contact with the stopper 133, a large part or a half or more of the roof portion 132f may be in contact with the stopper 133, or one point or a part of the roof portion 132f may be in contact with the stopper 133.

In the charged particle beam device, to prevent the curtaining, the angle of the surface of the sample having the observation target portion with respect to the emission direction of the ion beam can be adjusted when the sample is placed on the jig. The adjustment of the inclination angle of the sample when the sample is placed on the jig is usually performed by the operator. The operator tilts the sample by eye based on experience and fixes the sample to the jig with a carbon tape or the like. Therefore, the inclination angle of the sample placed on the jig may vary depending on the operator.

Since the jig 130 according to the first embodiment includes the sample fixing portion 132 and has a rotation mechanism, the sample can be easily inclined. Further, by setting the inclination angle of the roof portion 132f in advance, the rotation position can be accurately made to correspond to the set angle. That is, when the sample is replaced, a new sample is placed on the jig 130, and the sample fixing portion 132 is rotated, the same inclination angle as that of the previously placed sample can be obtained. Accordingly, it is possible to make the inclination angle of the sample placed on the jig, which could otherwise vary depending on the operator, uniform by using the jig 130.

The inclination angle of the sample may be calculated in advance such that the incidence direction of the ion beam 111 and a structure pattern in the sample do not overlap. By setting the inclination angle of the roof portion 132f to match the calculated inclination angle of the sample, the reproducibility of the angle adjustment is improved as compared with the case in which the sample is fixed to the jig by the operator by using a carbon tape or the like. That is, by using the jig 130 according to the present embodiment, when the sample 140 is viewed from the X direction, for example, a state in which the incidence direction of the ion beam 111 and the structure pattern in the sample 140 overlap can be avoided. That is, it is possible to easily implement a state in which the ion beam 111 is emitted from a direction inclined with respect to the surface of the sample 140 (a state in which the incidence direction of the ion beam 111 and the structure pattern in the sample do not overlap and the curtaining is less likely to occur). In addition, the reproducibility of the state can be improved. That is, even when the sample placed on the jig 130 is replaced, the angle between the incidence direction of the ion beam 111 with respect to the surface of the sample and the structure pattern in the sample can be made constant.

### Modifications

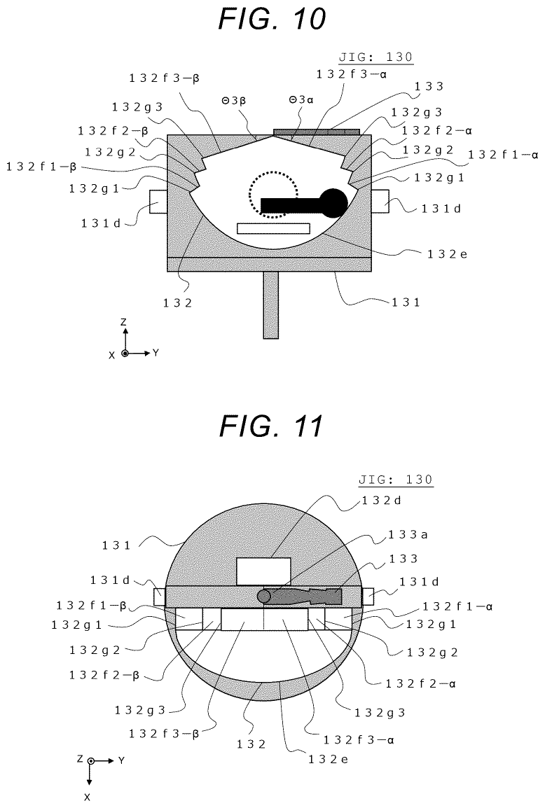

FIG. 10 is a side view illustrating a configuration example of the jig according to a modification of the first embodiment. FIG. 11 is a top view illustrating the configuration example of the jig 130 according to the modification of the first embodiment.

In the present modification, when the sample fixing portion 132 is viewed from the X direction, the roof portion 132f inclined from a circle center portion of the arc portion 132e is provided. In other words, the roof portion 132f may not be parallel to an upper surface of the wall portion 131b in the support portion 131. The roof portion 132f is inclined such that a circle center thereof is closest to the upper surface of the wall portion 131b and the roof portion 132f gradually moves away from the upper surface of the wall portion 131b. That is, the roof portion 132f is an upper surface of the sample fixing portion 132 that is inclined from the circle center toward the floor portion 131a. At this time, three roof portions 132f, such as 132f1, 132f2, and 132f3 are provided in the jig 130 in FIGS. 10 and 11. Similarly to the shoulder portion 132g1 and the shoulder portion 132g2 described above, a shoulder portion 132g3 is provided between the roof portion 132f2 and the roof portion 132f3.

For example, the sample fixing portion 132 may be processed into a shape having a plurality of the shoulder portions 132g by cutting end portions from a semicircular shape including the arc portion 132e. An extension line of each of the roof portions 132f may or may not overlap a circle center of the arc portion 132c.

Regarding the roof portion 132f in contact with the stopper 133, a large part or a half or more of the roof portion 132f may be in contact with the stopper 133, or one point or a part of the roof portion 132f may be in contact with the stopper 133. For example, the rotation of the sample fixing portion 132 may be stopped at least when the shoulder portion 132g comes into contact with a lower surface of the stopper 133.

The roof portion 132f3 includes, for example, a roof portion 132f3-α and a roof portion 132f3-β. The roof portion 132f3 has α and β. When the sample fixing portion 132 is viewed from the X direction, a rotation angle of the sample fixing portion 132 from a state in which the sample placement portion 132h and the rotation shaft 132d are held at initial positions until the stopper 133 to be described later and the roof portion 132f3 come into contact with each other is an inclination angle θ3α or θ3β.

The inclination angles θ3α and θ3β of the roof portion 132f3-α and the roof portion 132f3-β may be the same or different.

The stopper 133 according to the present modification includes two protruded portions to match the three roof portions 132f. Accordingly, even when there is a plurality of the roof portions 132f such as the roof portion 132f1, the roof portion 132f2, and the roof portion 132f3 in FIG. 11, each roof portion 132f can be brought into contact with the single stopper 133 by adjusting a rotation amount of the single stopper 133.

Other configurations and operations according to the present modification may be the same as those of the first embodiment. Even with the configuration according to the present modification, the same effects as those of the first embodiment can be obtained. The number of the roof portions 132f can be determined by the operator, and any number of the roof portions 132f may be provided. Further, the number of the stoppers 133 or the number of the protruded portions in the stopper 133 may be determined by the operator, and any number of the stoppers 133 and any number of the protruded portions may be provided.

### Second Embodiment

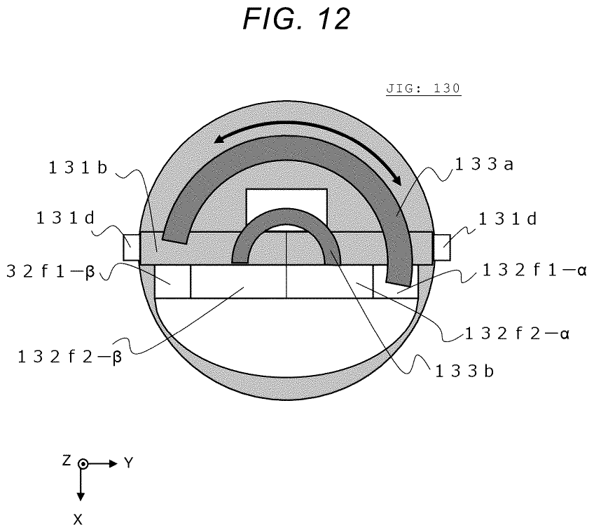

FIG. 12 is a top view illustrating a configuration example of the jig 130 according to a second embodiment. In the second embodiment, the jig 130 includes a plurality of arc-shaped stoppers 133.

For example, when a plurality of roof portions 132f are provided, the stoppers 133 may be provided for the roof portions 132f, respectively. That is, there may be a plurality of stoppers 133, such as a stopper 133a provided corresponding to the roof portion 132f1 and a stopper 133b provided corresponding to the roof portion 132f2.

The stopper 133 is provided on the upper surface of the wall portion 131b in the Z direction. The stopper 133 is fixed to the upper surface of the wall portion 131b to be rotatable in the X-Y plane. When viewed from the Z direction, a tip portion of the stopper 133 can protrude from the wall portion 131b in the X-Y plane. When the sample fixing portion 132 is rotated in a state in which the stopper 133 protrudes from the wall portion 131b, the roof portion 132f comes into contact with the lower surface of the stopper 133.

Circle centers of the arc-shaped stoppers 133a and 133b may coincide with, for example, a center of the upper surface of the wall portion 131b in the Z direction.

Other configurations and operations according to the second embodiment may be the same as those of the first embodiment. Even with the configuration according to the second embodiment, the same effects as those of the first embodiment can be obtained. Further, the stopper 133 can be provided to match the number of the roof portions 132f, and the plurality of stoppers 133 may be provided.

### Third Embodiment

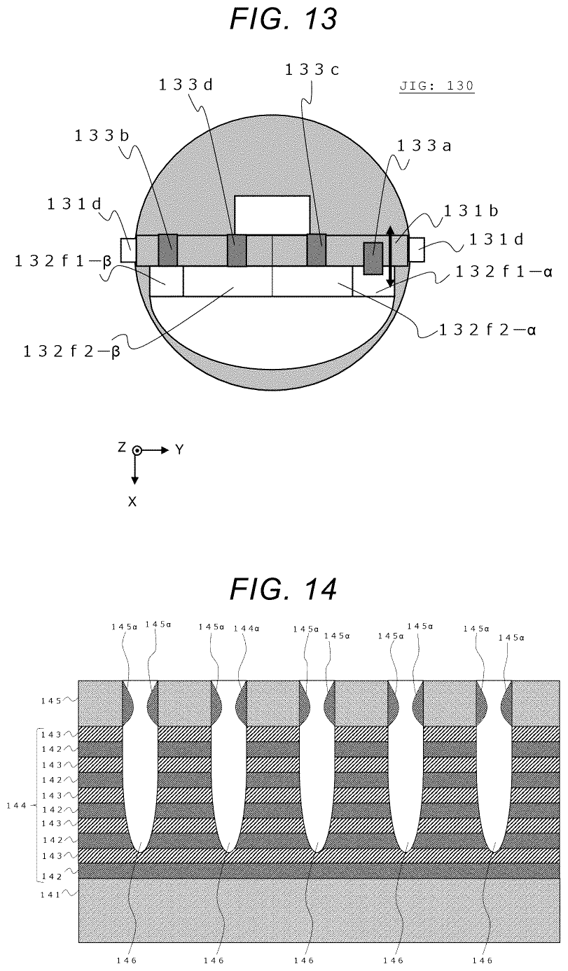

FIG. 13 is a top view illustrating a configuration example of the jig 130 according to a third embodiment. In the third embodiment, the jig 130 includes one or a plurality of stoppers 133 each having a quadrilateral shape.

For example, when a plurality of roof portions 132f are provided, the stoppers 133 may be provided for a and B in the roof portions 132f, respectively. That is, the plurality of stoppers 133 may be provided, such as a stopper 133a provided corresponding to the roof portion 132f1-α, a stopper 133b provided corresponding to the roof portion 132f1-β, a stopper 133c provided corresponding to the roof portion 132f2-α, and a stopper 133d provided corresponding to the roof portion 132f2-β.

The stopper 133 is provided on the upper surface of the wall portion 131b in the Z direction. The stopper 133 is fixed to the upper surface of the wall portion 131b. When viewed from the Z direction, the stopper 133 can protrude from the wall portion 131b in the X-Y plane. When the sample fixing portion 132 is rotated in a state in which the stopper 133 protrudes from the wall portion 131b, the roof portion 132f comes into contact with the lower surface of the stopper 133.

The stopper 133 can be provided to match the number of the roof portions 132f, and the plurality of stoppers 133 may be provided. Further, the stopper 133 can be detached from the wall portion 131b or is movable to slide along the upper surface of the wall portion 131b, and the stopper 133 can be moved to a position to match the roof portion 132f desired to be brought into contact with the stopper 133. That is, by providing one stopper 133 that is movable along the upper surface of the wall portion 131b, a disposition position of the stopper 133 can be changed to match the position of the roof portion 132f desired to be brought into contact with the stopper 133. In this case, the number of stoppers 133 can be reduced. Further, there is no need to change the shape of the stopper 133 to match the roof portion 132f.

When the stopper 133 can be detached and is movable along the upper surface of the wall portion 131b, the stopper 133 may be provided separately for each of the roof portions 132f on the left and right sides (each of α and β).

Other configurations and operations according to the third embodiment may be the same as those of the first embodiment. Even with the configuration according to the third embodiment, the same effects as those of the first embodiment can be obtained. The stopper 133 can be provided to match the number of the roof portions 132f, and the plurality of stoppers 133 may be provided. Further, the shape of the stopper 133 is not limited to a quadrilateral shape and may be, for example, a triangular shape.

### Fourth Embodiment

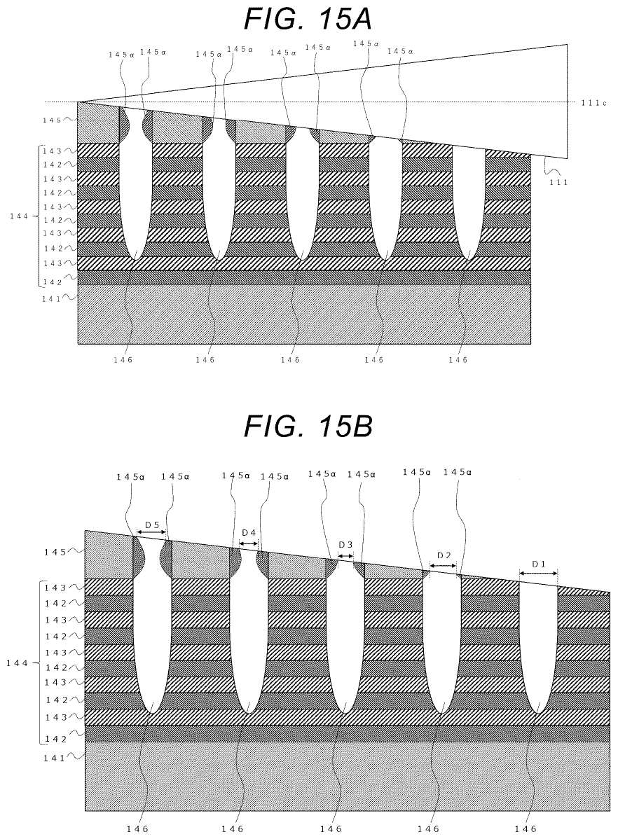

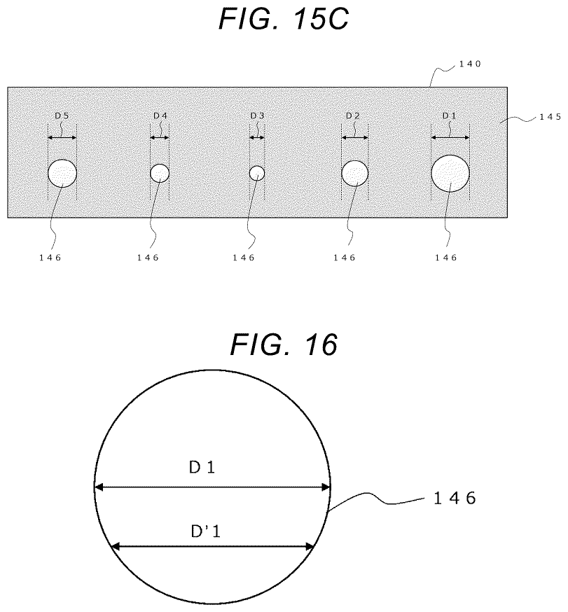

FIG. 14 is an enlarged view illustrating an example of a cross-sectional view of the sample 140 according to a fourth embodiment. FIGS. 15A to 15C are enlarged views of a cross-section or a top view of the sample 140 in the fourth embodiment during and after the emission of the ion beam 111.

FIG. 14 is an example of a cross-sectional view when the sample 140 is a semiconductor sample in the fourth embodiment. In the sample 140, a stacked film 144 in which a silicon oxide film 142 and a silicon nitride film 143 are alternately stacked on a substrate 141 is formed. When the hole 146 such as a memory hole or a contact hole is provided in the sample 140, a mask 145 having a shape corresponding to the hole 146 is provided on the stacked film 144. When etching for pattern formation is performed on the sample 140 in this state, a deposit 145a is accumulated on a side surface of the mask 145 as the stacked film 144 is processed and the hole 146 extends downward. It is noted that the hole 146 in the following description includes not only a hole in the stacked film 144 but also a hole in the mask.

When the deposit 145a is deposited on the side surface of the mask 145, a shape of the hole 146 may be affected. For example, an etching amount for a bottom of the hole 146 may decrease, and the hole 146 may become tapered as the hole 146 becomes deeper.

It is necessary to accurately examine how a diameter of the hole 146 changes in the depth direction and the shape of the hole 146 at different points. When examining whether the diameter of the hole 146 is uniform in the depth direction, it is possible to use the jig 130 according to the present disclosure to shave the sample 140 with the ion beam 111 from the FIB column 110 and observe the shaved sample 140 with the SEM column 120.

FIG. 15A is a cross-sectional view of the sample 140 in the fourth embodiment when the ion beam 111 is emitted. FIG. 15B is a cross-sectional view of the sample 140 in the fourth embodiment after emission of the ion beam 111. FIG. 15C is a top view of the sample 140 in the fourth embodiment after emission of the ion beam 111 and shows a top view of the hole 146 in the sample 140 after the sample is processed by the emission of the ion beam 111.

As illustrated in FIG. 15A, for example, the ion beam 111 emitted from the FIB column 110 may be emitted such that a central axis 111c of the ion beam 111 is substantially parallel to the surface of the sample 140 placed on the jig 130. In FIG. 15A, the ion beam 111 is emitted such that the central axis 111c is substantially parallel to the surface of the sample 140 placed on the jig 130. The FIB column 110 focuses the ion beam 111 toward one point. In other words, the ion beam 111 has a conical shape with a focal point as an apex and has a beam width, that is, an unfocused portion at locations other than the focal point. Therefore, when a portion of the sample 140 that is far from the FIB column 110 is set as the focal point of the ion beam 111, the sample 140 is processed along a shape of the ion beam 111 during the focusing (along the beam width).

FIG. 15B is a view when the emission of the ion beam 111 to the surface of the sample 140 illustrated in FIG. 15A is finished. As described above, a height from a bottom surface of the sample 140 to the upper surface of the sample 140 is different along the shape of the ion beam 111 during the focusing.

Here, when the state in FIG. 15B and FIG. 15C is measured by observing the surface of the sample 140 with the SEM column 120, sizes D1 to D5 of the diameter of the hole 146 in the surface of the sample 140 are compared. As a result, the diameters D1 to D5 of the hole 146 at different positions in the depth direction can be measured by the emission of the ion beam 112 at a time.

When it is desired to examine a change in the diameter of the hole 146 in the depth direction, it is also conceivable to perform the measurement by cutting the sample 140 such that the cross-section can be seen as illustrated in FIG. 14. However, in the observation of the cross-section of the sample 140, the diameter of the hole 146 is very small, and it is difficult to match the cross-section with the diameter of the hole 146.

FIG. 16 is a top view illustrating an example of a hole in the fourth embodiment. Although the diameter desired to be measured is D1 in the hole 146, the diameter of the hole 146 in the cross-section may be D′1 when the sample 140 is cut such that the cross-section can be seen.

In the present embodiment, the surface of the sample 140 is cut, and the processed surface of the sample 140 after being cut is observed by the SEM, and therefore the diameter of the hole 146 can be easily identified from the processed surface. Accordingly, it is possible to accurately examine a change in the pattern shape of the sample 140 in the depth direction.

In the jig 130 used in the present embodiment, the inclination angle of the sample 140 can be set by the sample fixing portion 132 and the stopper 133. For example, when the operator manually adjusts the inclination angle of the sample and repeatedly places a plurality of samples of the same type as the sample 140, the inclination angles of the respective samples may be significantly different. In this case, the orientation of the ion beam emitted to the surface of the sample also differs every time the sample is placed. Accordingly, when the ion beam 111 is obliquely incident on the sample surface, an interval between patterns (for example, the plurality of holes 146) differs every time the sample is replaced. Further, even in a pattern (for example, a plurality of holes 146) arranged in the same place in the same sample, the position of the pattern exposed from the processed surface of the sample may differ in the depth direction.

In contrast, by using the jig 130 according to the present embodiment, the inclination angle of the sample can be controlled by the sample fixing portion 132 and the stopper 133. Accordingly, even when the ion beam 111 is obliquely incident on the sample surface, the incident angle can be made the same. That is, the interval between the patterns (for example, the plurality of holes 146) can be made the same even when the sample is replaced, and the position of the pattern exposed from the processed surface of the sample in the depth direction can be made the same even in a pattern (for example, the plurality of holes 146) arranged in the same place in the same sample. Even when an examination related to pattern formation is performed many times using a plurality of the same samples, it is possible to accurately compare an inspection result with a previous or subsequent inspection result.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A jig comprising:
a support portion including a wall portion extending in a first direction and a second direction perpendicular to the first direction;
a rotatable sample fixing portion having a sample holding surface configured to allow a sample to be placed thereon and including a sample holding mechanism; and
a stopper provided on an upper surface of the wall portion and movable to a position where the sample fixing portion can come into contact therewith when the sample fixing portion is rotated.

2. The jig according to claim 1, wherein
the sample fixing portion further includes
a sample placement portion formed with the sample holding surface and including an arc portion when viewed from a third direction perpendicular to the first direction and the second direction, and
a rotation shaft extending from the sample placement portion in the third direction and penetrating the wall portion.

3. The jig according to claim 2, further comprising:
a fixing portion provided on a side surface of the wall portion, and configured to come into contact with the rotation shaft in the wall portion to prevent rotation of the rotation shaft.

4. The jig according to claim 2, wherein the sample fixing portion further includes a roof portion inclined from a tip portion that is at a circle center of the arc portion.

5. The jig according to claim 4, wherein the roof portion comprises at least two or more roof portions, and the two or more roof portions have different inclination angles from the tip portion.

6. The jig according to claim 5, wherein the stopper includes a plurality of protruded portions and the number of the protruded portions is one less than the number of the roof portions.

7. The jig according to claim 5, wherein the stopper includes a plurality of independently movable portions and the number of the independently movable portions is equal to the number of the roof portions.

8. The jig according to claim 4, wherein the stopper has a semicircular shape.

9. The jig according to claim 4, wherein the stopper is rotatably provided on the upper surface of the wall portion, and the sample fixing portion is rotated to the position where the sample fixing portion can come into contact therewith when the sample fixing portion is rotated.

10. The jig according to claim 9, wherein
when the stopper is rotated to a first position, a first one of the roof portions can come into contact therewith when the sample fixing portion is rotated, and
when the stopper is rotated to a second position, a second one of the roof portions can come into contact therewith when the sample fixing portion is rotated.

11. The jig according to claim 1, wherein the stopper is movable from an initial position on the upper surface of the wall portion where the stopper does not protrude from the wall portion when viewed in the first direction, to a stopper position where the stopper protrudes from the wall portion when viewed in the first direction.

12. The jig according to claim 1, wherein the sample holding mechanism includes a step provided on the sample holding surface and configured to support at least one edge of the sample.

13. The jig according to claim 1, wherein the sample holding mechanism includes a plate spring that presses the sample against the sample holding surface.

14. The jig according to claim 13, wherein the sample fixing portion further includes a step provided on the sample holding surface and configured to support at least one edge of the sample.

15. The jig according to claim 1, wherein when the sample fixing portion is at an initial position, the sample holding surface is inclined to form an acute angle with a normal direction of the wall portion when viewed in the second direction.

16. A method of processing a sample that is placed on a rotatable sample fixing portion of a jig, comprising:
fixing the sample to the sample fixing portion;
moving a stopper provided on the jig to a position that stops the rotation of the sample fixing portion;
rotating the sample fixing portion until the sample fixing portion is stopped by the stopper; and
mounting the jig on a sample processing device.

17. The method according to claim 16, wherein the stopper is rotated to the position.

18. The method according to claim 16, wherein the stopper is moved linearly to the position.

19. The method according to claim 16, wherein
a first upper surface of the sample fixing portion comes into contact with the stopper that is at a first position, after the sample fixing portion is rotated from an initial position thereof by a first angle, and
a second upper surface of the sample fixing portion comes into contact with the stopper that is at a second position, after the sample fixing portion is further rotated from the initial position thereof by a second angle.

20. The method according to claim 16, wherein a charged particle beam is emitted to process the sample after the jig is mounted on the sample processing device.
